(19) United States
(12) Patent Application Publication
(10) Pub. No.: US 2023/0112536 A1
(43) Pub. Date: Apr. 13, 2023

(54) METHOD FOR PRODUCING AN ELECTRONIC DEVICE HAVING A CIRCUIT BOARD CONTAINED IN A DEVICE HOUSING AND CONNECTION ELEMENTS CONNECTED TO THE CIRCUIT BOARD FOR CONNECTING ELECTRICAL CONNECTION CONDUCTORS

(71) Applicant: Phoenix Contact GmbH & Co. KG, Blomberg (DE)

(72) Inventor: Klas HELLMANN, Hameln (DE)

(21) Appl. No.: 17/910,759

(22) PCT Filed: Mar. 10, 2021
(86) PCT No.: PCT/EP2021/056080

§ 371 Date: Sep. 9, 2022

(30) Foreign Application Priority Data
Mar. 12, 2020 (DE) 102020106836.0

(51) Int. Cl. H01R 12/51; H05K 5/00; H01R 43/02

(52) U.S. Cl. CPC H01R 12/515; H05K 5/0069; H01R 43/0256; H01R 12/58

(57) ABSTRACT

A method for producing an electronic device for use within a switchgear cabinet, includes providing connection elements for the electronic device that are first integrated in a device housing provided for the electronic device. Then a circuit board for the electronic device is inserted in the device housing and the connection elements are connected to the circuit board.

### FIELD

The present invention relates to a method for producing an electronic device, more particularly for use within a switchgear cabinet, having a circuit board contained in a device housing and connection elements connected to the circuit board for connecting electrical connection conductors. The invention also relates to a device housing that can be used to produce an electronic device having a circuit board and connection elements connected to the circuit board for connecting electrical connection conductors, more particularly for use within a switchgear cabinet. In addition, the invention relates to an electronic device that can be produced by means of one of the aforementioned methods.

### BACKGROUND

Today, electronic devices usually consist of one or more circuit boards, a housing and the appropriate connection technology to supply the device with energy and/or signals or data, etc. In the field of devices with a degree of protection sufficient for use in a switchgear cabinet in particular, the connection is usually made via a connection element soldered onto or into the circuit board. The circuit board provided with the connection element is then assembled in the respective housing.

Mechanical forces that are brought to the connection element by the connected cable are either dissipated via the circuit board to the housing or by additional attachment of the connection elements to the housing directly from the connection element to the housing. In the case of pure SMD assembled components in particular (SMD: surface-mounted device), more particularly in the case of connection elements SMD soldered to a circuit board, it is necessary here that the forces applied to the connection elements after assembly in a device housing are dissipated via the housing in order to avoid impermissible or excessive forces on the SMD solder joint. For the soldering of the connection elements on the circuit board, the circuit board comprises correspondingly designed contact elements, e.g. contact elements designed as contact pins, which are soldered to a soldering pad provided on the circuit board. In all of the cases mentioned above, the connection elements are assembled from corresponding individual elements and are correspondingly soldered to the circuit board. In the event that the components on the circuit board are soldered in a soldering furnace, it is necessary for the connection elements to withstand this temperature. If this is not the case, a corresponding additional processing step is necessary to apply the contact element to the circuit board (e.g., selective soldering).

In the current solutions for the combination of a circuit board, in particular an SMD-equipped circuit board, a connection element and a housing, it can be seen that, depending on the procedure, certain process steps must be run through more than once. For example, the individual assembly steps for assembling the connection elements on the circuit board and the subsequent assembly in the device housing must be repeatedly interrupted by soldering steps. If the connection elements are soldered together with the contact elements in the soldering furnace, more particularly with SMD contact elements or THR contact elements (THR: through-hole-reflow technology), there are also restrictions on the housing material, since not every plastic can withstand this process without undesired changes. As is known, in THR technology, unlike in SMD technology, contact pins are inserted into corresponding contact holes provided with solder paste and then soldered.

In addition, the problem persists that the forces introduced via the connection elements when attaching the connection conductors cannot be safely absorbed and dissipated without a corresponding, additional embodiment of a connection element, a circuit board and a housing without damaging the solder joints or contact points between the contact elements of the connection elements and the circuit board.

### SUMMARY

One object of the present invention is to provide a simplified method for producing electronic devices, more particularly for use within a switchgear cabinet, which significantly reduces or even prevents harmful mechanical stress on the contact point between the connection element and the circuit board in the simplest electronic device production.

The invention proposes a method having the features of independent claim 1 as a solution. Furthermore, the invention proposes a device housing suitable for such a method in accordance with claim 7, along with an electronic device in accordance with claim 11 that can be produced by means of such a method.

Further advantageous configurations according to the invention are the subject matter of the dependent claims.

The invention consequently proposes a method for producing an electronic device, with which the connection elements provided for an electronic device are first integrated in a device housing provided for the electronic device and then a circuit board provided for the electronic device is inserted in the device housing and the connection elements are connected, i.e. in particular electronically and mechanically connected, to the circuit board.

An essential advantage of the solution in accordance with the invention is that only one continuous assembly process and possibly a subsequent soldering process are required. It is also ensured that the mechanical forces introduced via the connection elements after production and when the connection conductors are attached are transmitted directly to the device housing, so that damaging mechanical stress on the contact points between the connection elements and the circuit board no longer occurs, or at least is significantly reduced.

For a device housing that is particularly suitable for the production of such an electronic device in accordance with the invention, it is also proposed that said device housing is designed for, on the one hand, integrating connection elements provided for the electronic device and provides a through-opening through which electrical connection conductors can be fed to the connection elements from outside into the housing in order to establish a connection to the connection elements, or through which the connection elements may extend out of the housing for connecting to electrical connection conductors. On the other hand, the device housing is designed, with connection elements that are already integrated, for inserting the circuit board provided for the electronic device in the device housing.

The method is advantageously suitable for differently designed components and can consequently be used in a versatile and flexible manner. In particular, it can be provided that the electronic and mechanical connection of the connection elements to the circuit board and connection technology is at least partially effected when the circuit board is inserted, or the complete electronic and mechanical connection of the connection elements and the circuit board is carried out or at least completed in a separate method step only after the circuit board has been inserted.

Additionally or alternatively, a part of the housing can already be formed by inserting the circuit board itself, or the device housing can comprise at least two housing parts to be connected to one another, wherein the connection elements are integrated in one of the housing parts and the two housing parts are connected after the circuit board has been inserted in the same or another housing part.

In accordance with advantageous developments of the invention, connection elements may be used with contact pins that are pressed into correspondingly formed contact holes in the circuit board in order to establish a connection, and/or are used with contact springs that are pressed onto correspondingly formed contact surfaces on the circuit board in order to establish a connection.

Additionally or alternatively, a device housing comprising a material that is sufficiently heat-resistant to undergo a soldering process is used, and the connection elements are at least partially provided with SMD or THR contact elements that are soldered by means of a soldering process in order to establish a complete, in particular electrical and mechanical, connection, with correspondingly designed contact surfaces or holes on the circuit board.

In accordance with a further advantageous development of the invention, the connection elements used are connection elements that are suitable for connecting individual line wires, in particular connection elements with screw or clamp connections designed for this purpose.

The advantages of a device housing designed for the developments described above result accordingly.

In particular, in accordance with a further advantageous development of the device housing, it is provided that said device housing is designed to effect an at least partial connection, in particular an electrical and/or mechanical connection, between the connection elements and the circuit board when the housing parts are joined together.

### BRIEF DESCRIPTION OF THE DRAWINGS

These and further features and advantages of the present invention can also be found in the exemplary embodiments, which are explained in more detail below with reference to the accompanying drawings. The following are shown in schematic representation:

FIG. 1 a first exemplary embodiment of an electronic device that can be produced in accordance with the invention;

FIG. 2 an electronics housing that can be used for a method in accordance with the invention for producing the electronic device shown in FIG. 1 in 3 views;

FIG. 3 the electronics housing in accordance with FIG. 2 having connection elements integrated therein;

FIG. 4 a circuit board that can be inserted in the electronics housing for producing the electronic device in accordance with FIG. 1;

FIG. 5 a further exemplary embodiment of an electronic device that can be produced in accordance with the invention in 2 views; and

FIG. 6 an example of a second housing part for the electronics housing in accordance with FIG. 2.

### DETAILED DESCRIPTION

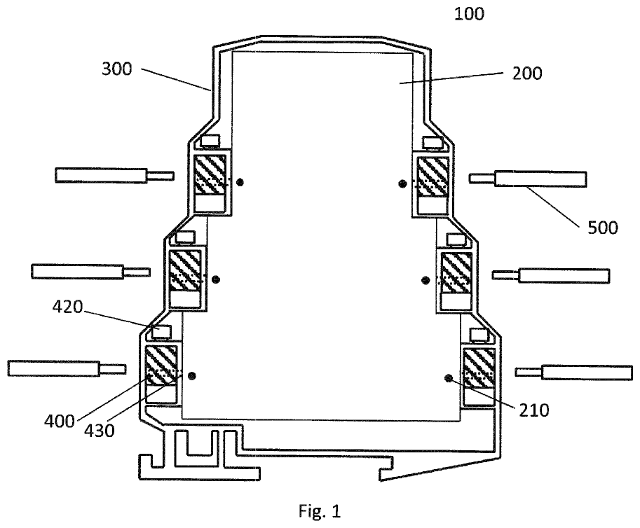

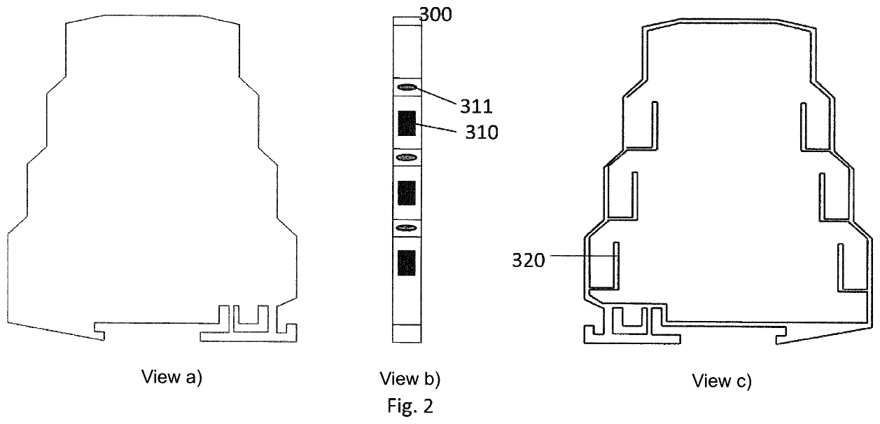

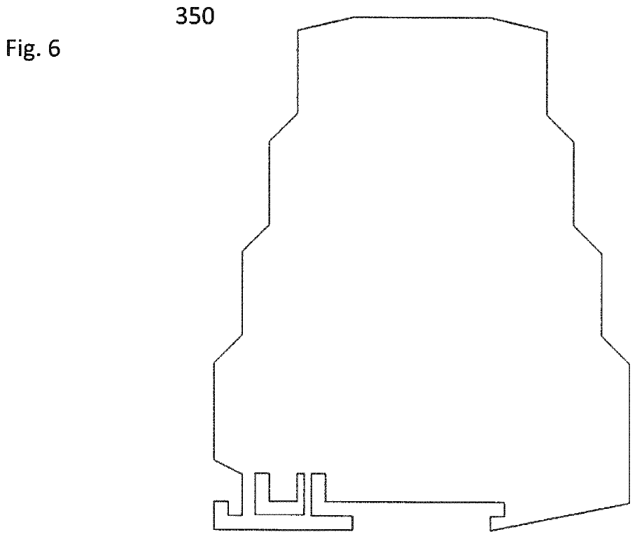

FIG. 1 shows, by way of example, a first exemplary embodiment of an electronic device 100 that can be produced in accordance with the invention in a partially sectioned view, more particularly for use within a switchgear cabinet, having a circuit board 200 contained in a device housing 300 and connection elements 400 connected thereto for connecting electrical connection conductors 500, which can be produced using a method that is described in detail below. The connection elements 400 in turn make contact with electrical conductors of the circuit board 200 by means of contact elements 430 (shown in dashed lines in FIG. 1) they comprise. For this purpose, corresponding contact points 210 are provided on the circuit board, via which contact with the contact elements 430 of the connection elements 400 is established. Of course, more than just one circuit board 200 may also be included. The device housing 300 shown is an example of a multi-part device housing for mounting on a DIN rail. A first housing part can be seen here, in which both the connection elements 400 have been integrated and the circuit board has also been inserted. Such a device housing 300, in particular the first housing part thereof, for producing the electronic device shown in FIG. 1 is shown in FIG. 2 in three views, specifically without integrated connection elements and without an inserted circuit board. View 2a shows the device housing from behind, view 2b laterally from one side and view 2c from the front. A second housing part 350 that completes the device housing, e.g. as a cover, and that is connected to the first housing part shown in FIG. 1 and also in FIG. 2, is shown in FIG. 6 by way of example. Both housing parts may be appropriately glued together in the present case. Alternatively or additionally, however, separate connecting means may also be provided, in particular for establishing a screw, clamp or latching connection.

The connection elements 400 shown in FIG. 1 with the connection conductors 500 to be connected thereto are designed, for example, for connecting individual line wires and the connection conductors 500 are consequently designed as a plurality of individual line wires. The electronic device can be supplied with energy, signals and/or data, etc. via such or similar connection technology, as is known per se to a person skilled in the art.

In order to connect the electrical connection conductors 500 to the connection elements 400, through-openings 310 (FIG. 2) are provided by the device housing, through which said electrical connection conductors can be fed to the connection elements 400 from outside into the housing 300. Additionally or alternatively, but not shown separately in the drawings for reasons of clarity, the connection elements may also extend at least partially out of the housing 300 for connection to electrical connection conductors 500 through such or similar through-openings. When the electrical connection conductors 500 are connected to the connection elements 400, a contact is established between the connection conductor 500 and the contact element 430 in a manner known per se. In order to hold the connection conductors 500 and make contact with the respective contact elements 430, the connection elements 400 are provided in an expedient embodiment, depending on the embodiment, with suitable holding and/or pressing devices 420, in a particularly expedient embodiment e.g. with screw or clamp connections. In the case of holding and/or pressing devices 420 that are to be actuated manually, for example also by means of a tool, such as in particular with screw or clamp connections, the device housing expediently provides further through-openings 311 (FIG. 2), through which access from the outside can be guaranteed.

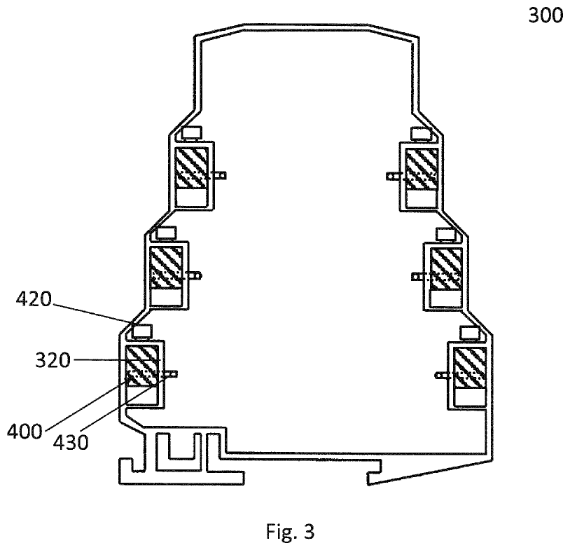

For the integration of the connection elements, FIG. 2 also shows, by way of example, six positions at which connection elements may be integrated. For this purpose, the device housing may be designed, for example, with a type of pockets or formations 320 in which the connection elements can be accommodated (cf. also FIG. 1 or 3).

FIG. 3 shows, by way of example, the device housing 300 with connection elements 400 that are already integrated, but with a circuit board that has not yet been inserted. The connection elements 400 with their contact elements 430 and holding and/or pressing devices 420 are accommodated here for integration in the formations 320 of the device housing. The formations 320, by way of example, and thus the device housing 300 can also, for example, form the function of a housing for the connection element 400.

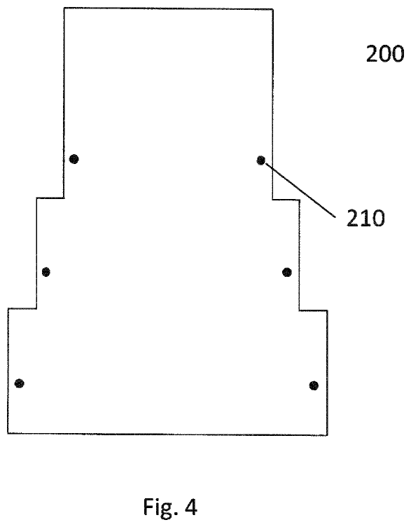

A circuit board 200 provided for the electronic device is shown by way of example in FIG. 4 and can be inserted from the front in accordance with the device housing embodiment shown in FIGS. 1 to 3, i.e. in accordance with view 2c in the direction of the drawing plane.

The connection elements 400 are integrated in the device housing in such a way that the contact points 210 of the circuit board 200 provided for the electronic device and the contact elements 430 of the connection elements may come into contact after the circuit board 200 has been inserted and may subsequently be electronically and mechanically connected to one another.

There are several options within the scope of the invention for establishing the electronic and mechanical connection of the connection elements 400 to the circuit board 200. In particular, such a connection can be at least partially effected when the circuit board 200 is inserted, or the complete electronic and mechanical connection of the connection elements 400 and the circuit board 200 can be carried out or at least completed in a separate method step only after the circuit board 200 has been inserted.

For example, the contact elements 430 may be designed as contact pins and the contact points 210 as contact holes, so that the contact pins are already pressed into the holes when the circuit board is inserted (cf. FIGS. 1 to 3) and are at least partially electronically and mechanically connected to one another.

Alternatively, the contact elements 430 may be designed as contact springs and the contact points 210 as contact surfaces, so that, for example, when the circuit board is inserted (cf. FIGS. 1 to 3), the contact springs are pressed against the contact surfaces for at least partial electronic and mechanical connection.

If, as a modification of the embodiment in accordance with FIGS. 1 to 3, the circuit board is not inserted in the same housing part as the connection elements, but in a separate housing part, which is only subsequently connected to the housing part in which the connection elements are integrated, the above-described, at least partial electronic and mechanical connection can also be effected, for example, only when the housing parts are assembled, in particular by applying appropriate force to the contact elements and the circuit board.

Additionally or alternatively, the contact elements 430 of the connection elements 400 may also be in the form of SMD contact elements, so that the complete connection is only established by a subsequent soldering process, not shown in the drawings for reasons of clarity. In this variant, the device housing 300 is expediently designed in such a way, i.e. in particular made of a sufficiently heat-resistant material, that it can withstand the soldering process, e.g. in the soldering furnace, without damage.

As an alternative to using SMD technology, THR technology can also be used, for example. In this case, both the contact elements 430 are designed as THR contacts and the contact points 210 of the circuit board 200 are designed as THR holes. Complete connection is also only established by a soldering process.

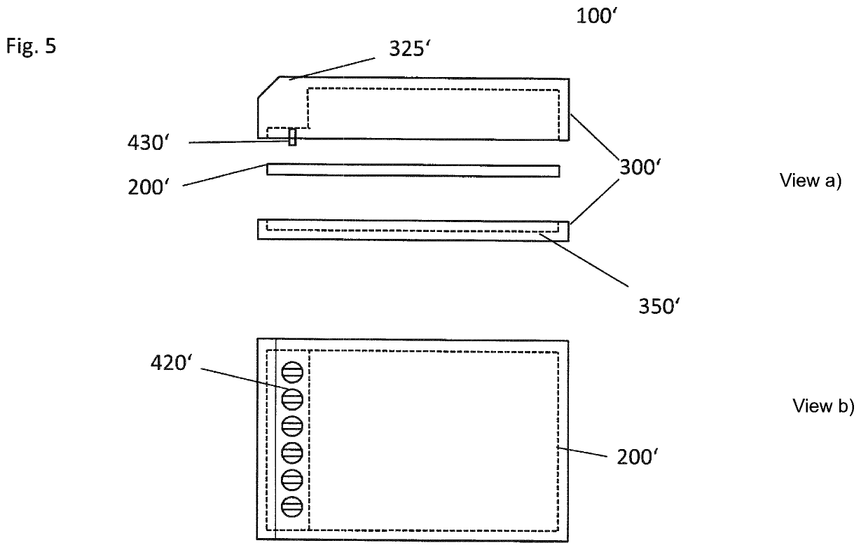

FIG. 5 shows, by way of example, a further embodiment of an electronic device 100′ that can be produced in accordance with the invention in 2 views. View 5a shows the electronic device in a lateral view and before assembly, i.e. in particular in an exploded view. View 5b shows the electronic device from above with partially internal components visible (dashed).

In a modification of the embodiment in accordance with FIGS. 1 to 3, the device housing 300′ substantially completely assumes the function of a connection element housing for integrating the connection elements. Only the contact elements 430′, designed as pins in accordance with FIG. 5, and the holding and pressing devices 420′ protrude from a first housing part 325′ and are accessible from the outside.

The circuit board 200′ provided for the electronic device 100′ can be inserted in the same housing part 325′ in a simple manner for producing this electronic device, in accordance with FIG. 5 from below. By inserting the circuit board 200′, a part of the housing 300′ can already be formed by this itself. Alternatively, a further housing part 350′ can be provided, which is connected to the first housing part 325′, e.g. in the manner of a cover, after the circuit board 200′ has been previously inserted. In a further alternative embodiment, it can also be provided that the circuit board 200′ is first inserted in the further housing part 350′ and then both housing parts are connected to one another.

In summary, the invention is therefore also based on the concept that a contact element 430 or 430′, which is part of a connection element, is integrated as part of the device housing 300 or 300′, that the device housing 300 or 300′ is designed for this purpose in such a way that it can accommodate the contact elements 430 or 430′ along with a device for holding and pressing the connected connection conductors onto the contact element and expediently furthermore that the device housing assumes the function of a connection element housing, in particular including housing insulation and/or holding together the components comprised by the connection element.

1. A method for producing an electronic device for use within a switchgear cabinet, comprising the steps of
integrating connection elements provided for the electronic device within a device housing provided for the electronic device,
subsequently inserting a circuit board provided for the electronic device in the device housing and electronically and mechanically connecting the connection elements to the circuit board, the connection elements for connecting electrical connection conductors.

2. The method in accordance with claim 1, wherein:
the electronic and mechanical connection of the connection elements to the circuit board is at least partially effected when the circuit board is inserted, or the complete electronic and mechanical connection of the connection elements and the circuit board is carried out or at least completed in a separate method step only after the circuit board has been inserted.

3. The method according to claim 1, wherein a part of the housing is formed by inserting the circuit board itself, or wherein the device housing comprises at least two housing parts to be connected to one another, wherein the connection elements are integrated in one of the housing parts and the two housing parts are connected after the circuit board has been inserted in the same or another housing part.

4. The method according to claim 1, wherein the connection elements are provided with contact pins as contact elements, which are pressed into contact points of the circuit board correspondingly designed as contact holes in order to establish a connection, or the connection elements are provided with contact springs as contact elements, which are pressed onto correspondingly designed contact surfaces as contact elements of the circuit board in order to establish a connection.

5. The method according to claim 1, wherein the device housing is made of a material that is sufficiently heat-resistant to undergo a soldering process, and the connection elements are provided with SMD or THR contact elements that are soldered by means of a soldering process in order to establish a complete, in particular electrical and mechanical, connection, with correspondingly designed contact surfaces or holes on the circuit board.

6. The method according to claim 1, wherein connection elements for connecting conductors are integrated as connection elements with screw or clamp connections, holding and/or pressing devices designed for this purpose.

7. A device housing for producing an electronic device having a circuit board and connection elements connected to the circuit board for connecting connection conductors according to claim 1, wherein:
the device housing is designed for integrating connection elements provided for the electronic device and provides a through-opening through which electrical connection conductors can be fed to the connection elements from outside into the housing in order to establish a connection to the connection elements, or through which the connection elements extend out of the housing for connecting to electrical connection conductors, and
the device housing is designed with connection elements already integrated, for inserting a circuit board provided for the electronic device in the device housing.

8. The device housing according to claim 7, comprising a material that is sufficiently heat-resistant to undergo a soldering process.

9. The device housing according to claim 7, comprises at least two housing parts to be connected to one another and is designed for integrating the connection elements in one of the at least two housing parts and for inserting the circuit board in another one of the at least two housing parts.

10. The device housing according to claim 9, wherein the device housing is further designed to effect an at least partial electrical and/or a mechanical connection, between the connection elements and the circuit board when the at least two housing parts are joined together.

11. An electronic device for use within a switchgear cabinet, having a circuit board contained in a device housing and connection elements connected to the circuit board for connecting electrical connection conductors, wherein the electronic device is produced by a method according to claim 1.
